(19) United States
(12) Patent Application Publication
(10) Pub. No.: US 2021/0226149 A1
(43) Pub. Date: Jul. 22, 2021

(54) PACKAGING SUBSTRATE, ELECTRONIC DEVICE, PACKAGING METHOD, AND PRESSING MOULD

(71) Applicant: BOE TECHNOLOGY GROUP CO., LTD., Beijing (CN)

(72) Inventors: Chengyuan LUO, Beijing (CN); Huaiting SHIH, Beijing (CN)

(21) Appl. No.: 16/646,477

(22) PCT Filed: Jul. 24, 2019
(86) PCT No.: PCT/CN2019/097535

§ 371 Date: Mar. 11, 2020

(30) Foreign Application Priority Data
Sep. 17, 2018 (CN) 201811080589.5

(51) Int. Cl. H01L 51/52; H01L 51/56

(52) U.S. Cl. CPC H01L 51/524; H01L 51/56; H01L 51/5253

(57) ABSTRACT

A packaging substrate, an packaging method and a pressing mould for the packaging method are disclosed. The packaging substrate includes a cover plate and a substrate which are oppositely arranged; a sealed member positioned between the cover plate and the substrate; a connecting part connecting the cover plate and the substrate and positioned at the periphery of the sealed member; and an inorganic layer located outside the connection part and between the cover plate and the substrate. At least a part of the inorganic layer is formed on the outer side surface of the connection part, and an orthographic projection of the inorganic layer on the substrate is located outside an orthographic projection of the sealed member on the substrate.

### CROSS REFERENCE TO RELATED APPLICATIONS

This application claims priority to the Chinese Patent Application No. 201811080589.5, filed Sep. 17, 2018, the entire disclosure of which is incorporated herein by reference as part of the present application.

### TECHNICAL FIELD

The embodiments of the disclosure relate to a packaging substrate, an electronic device, a packaging method, and a pressing mould for the packaging method.

### BACKGROUND

Organic Light Emitting Diode (OLED) display technology is a display technology that has attracted much attention in recent years, and has the characteristics of rich color gamut, high contrast, flexibility, and ultra-thinness, and therefore, it is regarded as the next generation of display technology. In the OLED display technology, because OLED devices may be corroded and damaged under the effect of water vapor and oxygen, the OLED devices need to be encapsulated or packaged.

### SUMMARY

Embodiments of the disclosure provide a packaging substrate, an electronic device, a packaging method, and a pressing mould for the packaging method, and the embodiments of the disclosure are beneficial to realizing narrow frame design.

At least one embodiment of the present disclosure provides a packaging substrate, which includes: a cover plate and a substrate, which are oppositely arranged; a sealed member, positioned between the cover plate and the substrate; a connection part, connecting the cover plate and the substrate, and comprising a part located at a periphery of the sealed member; and an inorganic layer, located at an outside of the connection part facing away from the sealed member, and located at least between the cover plate and the substrate. At least a part of the inorganic layer is formed on an outside surface of the connection part, the outside surface of the connection part is a surface of the connection part facing away from the sealed member in a direction parallel to the substrate, and an orthographic projection of the inorganic layer on the substrate is located outside an orthographic projection of the sealed member on the substrate.

For example, the at least part of the inorganic layer is in direct contact with the connection part; and/or the inorganic layer is in direct contact with the cover plate.

For example, an extension length of the at least part of the inorganic layer is greater than a thickness of the at least part of the inorganic layer.

For example, the inorganic layer includes the inorganic layer comprises a substrate-side extension part, a middle part, and a cover plate-side extension part, which are sequentially connected, the middle part is formed on the outside surface of the connection part, and the substrate-side extension part and cover plate-side extension part are both extended in a direction parallel to the substrate, and are located at the outside of the connection part.

For example, the at least part of the inorganic layer has an arc-shaped structure.

For example, an inner surface of the at least part of the inorganic layer is a convex surface protruding toward the sealed member, and the inner surface is at last a part of a surface facing the sealed member.

For example, the connection part is in direct contact with the cover plate.

For example, the connection part includes a main body part covering the sealed member, and a peripheral part located at a periphery of the sealed member and connected to the main body part.

For example, the outside surface of the connection part, on which the inorganic layer is formed, is an arc-shaped surface.

For example, the packaging substrate further includes a first organic layer and an outer inorganic layer, which are both located at an outside of the inorganic layer; the outside of the inorganic layer is a side of the inorganic layer facing away from the sealed member in a direction parallel to the substrate; and in the direction parallel to the substrate, the first organic layer is located between the inorganic layer and the outer inorganic layer.

For example, the outer inorganic layer is connected with a side surface of the cover plate.

For example, the packaging substrate further includes an interlayer inorganic layer and a second organic layer, in the direction parallel to the substrate, located between the first organic layer and the outer inorganic layer; the second organic layer is located between the interlayer inorganic layer and the outer inorganic layer in the direction parallel to the substrate.

For example, the packaging substrate further includes a thin film packaging layer located at a side of the connection part facing the sealed member, and the thin film packaging layer covers the sealed member, and a periphery of the thin film packaging layer is located outside the sealed member, and connected with the substrate.

At least one embodiment of the present disclosure provides an electronic device, which includes the packaging substrate according to any one of the above embodiments, and the electronic device is a display device or a light emitting device.

At least one embodiment of the present disclosure provides a packaging method, which includes: connecting a first base substrate and a second base substrate formed with a sealed member by using a paste, wherein a pressing mould located at a periphery of the sealed member is arranged between the first base substrate and the second base substrate; performing a press processing on the paste; curing the paste that has been subjected to the press processing to obtain a connecting part connecting the first base substrate and the second base substrate; cutting the first base substrate and the second base substrate to obtain a cover plate and a substrate respectively; and forming an inorganic layer on an outside of the connection part facing away from the sealed member, and at least between the cover plate and the substrate, wherein at least a part of the inorganic layer is formed on an outside surface of the connection part, the outside surface of the connection part is a surface of the connection part facing away from the sealed member in a direction parallel to the substrate, and an orthographic projection of the inorganic layer on the substrate is located outside an orthographic projection of the sealed member on the substrate.

For example, the inorganic layer is formed by an atomic layer deposition method.

For example, forming the inorganic layer includes: forming a removable layer on the cover plate and the substrate; forming an inorganic layer thin film covering an outer surface of the removable layer and an outer surface of the connection part; and removing the removable layer to obtain the inorganic layer.

For example, the surface of the pressing mould facing the paste is coated with a release agent.

For example, before connecting the first base substrate and the second base substrate formed with the sealed member by using the paste, a paste pattern is formed on the first base substrate or the second base substrate, and a region corresponding to the paste pattern does not completely overlap with a region corresponding to the sealed member.

For example, a thickness of the paste pattern is 1.5-3 times as large as a distance between the cover plate and the substrate.

At least one embodiment of the present disclosure provides a packaging method, which includes: connecting a cover plate with a substrate on which a sealed member is formed by using a paste, wherein a pressing mould located at a periphery of the sealed member is arranged between the cover plate and the substrate; performing a press processing the paste; curing the paste that has subjected to the press processing to obtain a connecting part connecting the cover plate and the substrate; and forming an inorganic layer on an outside of the connection part facing away from the sealed member, and at least between the cover plate and the substrate, wherein at least a part of the inorganic layer is formed on an outside surface of the connection part, the outside surface of the connection part is a surface of the connection part facing away from the sealed member in a direction parallel to the substrate, and an orthographic projection of the inorganic layer on the substrate is located outside an orthographic projection of the sealed member on the substrate

At least one embodiment of the present disclosure provides a pressing mould for the packaging method according to any one of the above embodiments. The pressing mould includes a plurality of first extension parts and a plurality of second extension parts. The plurality of first extension parts and the plurality of second extension parts cross each other to form a grid-like structure, and oppositely facing side surfaces of adjacent first extension parts and oppositely facing side surfaces of adjacent second extension parts are arc-shaped surfaces.

### BRIEF DESCRIPTION OF THE DRAWINGS

In order to clearly illustrate the technical solution of the embodiments of the disclosure, the drawings of the embodiments will be briefly described in the following; it is obvious that the described drawings are only related to some embodiments of the disclosure and thus are not limitative of the disclosure.

FIG. 1 is a schematic cross-sectional view of a packaging substrate using a thin film encapsulation method;

FIG. 2 to FIG. 5 are schematic cross-sectional views of packaging substrates according to embodiments of the present disclosure;

FIG. 6 is a schematic cross-sectional view of a part of a structure in a packaging substrate provided by an embodiment of the disclosure;

FIG. 7 is a schematic top view of a part of a structure in a packaging substrate provided by an embodiment of the disclosure;

FIG. 8A to FIG. 14 are schematic diagrams of the substrates obtained in each step of the packaging method provided by an embodiment of the disclosure;

FIG. 15A is a schematic top view of a pressing mould provided by an embodiment of the disclosure; and

FIG. 15B is a schematic sectional view taken along the line AA in FIG. 15A.

### DETAILED DESCRIPTION

In order to make objects, technical details and advantages of the embodiments of the disclosure apparent, the technical solutions of the embodiments will be described in a clearly and fully understandable way in connection with the drawings related to the embodiments of the disclosure. Apparently, the described embodiments are just a part but not all of the embodiments of the disclosure. Based on the described embodiments herein, those skilled in the art can obtain other embodiment(s), without any inventive work, which should be within the scope of the disclosure.

Unless otherwise defined, all the technical and scientific terms used herein have the same meanings as commonly understood by one of ordinary skill in the art to which the present disclosure belongs. The terms “first,” “second,” etc., which are used in the description and the claims of the present disclosure, are not intended to indicate any sequence, amount or importance, but distinguish various components. The terms “comprise,” “comprising,” “include,” “including,” etc., are intended to specify that the elements or the objects stated before these terms encompass the elements or the objects and equivalents thereof listed after these terms, but do not preclude the other elements or objects. The phrases “connect”, “connected”, etc., are not intended to define a physical connection or mechanical connection, but may include an electrical connection, directly or indirectly. “On,” “under,” “right,” “left” and the like are only used to indicate relative position relationship, and when the position of the object which is described is changed, the relative position relationship may be changed accordingly.

At present, among various packaging methods of OLED devices, the packaging film used in a thin film encapsulation (TFE) method has the characteristics of relatively thin thickness and high barrier, therefore, the thin film encapsulation method is easy to be combined with other packaging methods to jointly ensure the reliability of devices. FIG. 1 is a schematic cross-sectional view of a packaging substrate using a thin film encapsulation method. As shown in FIG. 1, a sealed member 03 is formed on a substrate 02, and the sealed member 03 is covered with a packaging thin film, and the packaging thin film includes a first inorganic barrier layer 05, an organic barrier layer 06, and a second inorganic barrier layer 07, which are sequentially laminated.

For example, the manufacturing method for an inorganic layer in the thin film encapsulation process includes chemical vapor deposition (CVD), physical vapor deposition (PVD) or atomic layer deposition (ALD), etc. In research, the inventors of the present disclosure noticed that a mask plate is required in the process of forming the inorganic layer by the above deposition methods; however, there is a certain gap between a mask plate and the substrate 02, resulting in an thinner film edge 051 or 071 after the material for forming the inorganic layer enters the gap between the mask plate and the substrate 02, as shown in FIG. 1. These film edges 051/071 are much thinner than the required Elm 05/07 (e.g., less than 90% of the required thickness), and the region where these film edges 051/071 arc located can extend outward by more than 200 μm, thus generating a shadowing effect; especially, for the atomic layer deposition method with a good packaging effect, the influence range of the shadowing effect can even reach up to millimeter level. The inventors of the present disclosure have also noticed that, because the thin film encapsulation method includes multilayer films that are sequentially stacked, the layer(s) manufactured later covers the shaded part (i.e., thinner film edge) of the layer that is manufactured earlier in the process of preparing the multilayer film, so the overlapping of the shaded parts of multiple layers causes the border of the packaging substrate to become wider, which is contrary to the current design trend of a narrow border.

Embodiments of the disclosure provide a packaging substrate, an electronic device, a packaging method, and a pressing mould for the packaging method. In the embodiments of the present disclosure, the packaging substrate includes a cover plate and a substrate which are connected together through a connecting part, and an inorganic layer which does not cover the sealed member on the substrate is formed on the outside surface of the connecting part, so that the inorganic layer, located at the side surface of the packaging substrate (the side of the packaging substrate in a direction in which the substrate is extended) does not generate a shadowing effect, and is contributed to realize a narrow frame design. For example, in the embodiments of the present disclosure, the press processing may be performed on the paste for forming the connection part by using a pressing mould, and then the paste that has been subjected to the press processing is cured to obtain the connection part, and the outside surface of the connection part formed in this way is convenient for depositing the inorganic layer on the outside surface.

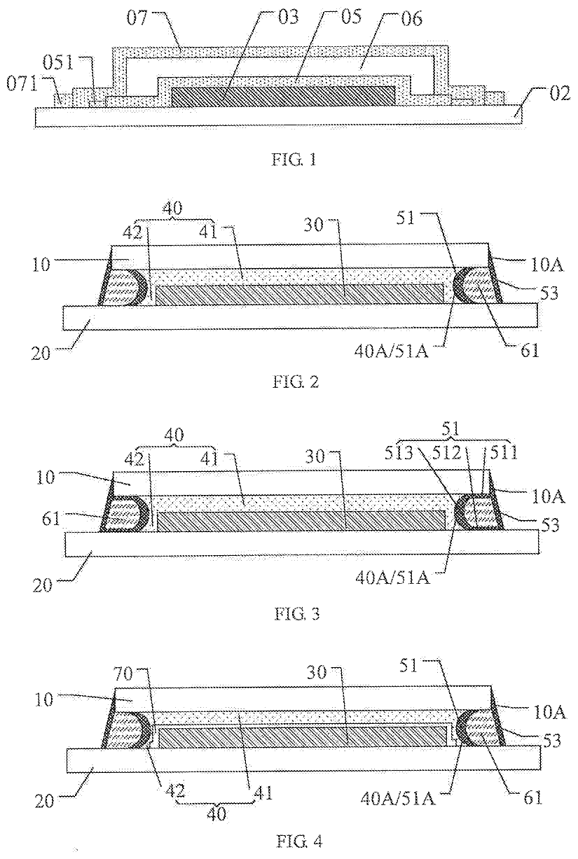

For example, as shown in FIG. 2 to FIG. 5, at least one embodiment of the present disclosure provides a packaging substrate including a cover plate 10, a substrate 20, a sealed member 30, a connection part 40, and an inorganic layer 51. The cover plate 10 and the substrate 20 are oppositely disposed. The sealed member 30 is located between the cover plate 10 and the substrate 20. The connection part 40 is arranged to connect the cover plate 10 and the substrate 20, and includes a part located at the periphery of the sealed member 30. The inorganic layer 51 is located at the outside of the connection part 40 (i.e., the side of the connection part 40 facing away from the sealed member 30), and at least between the cover plate 10 and the substrate 20. The inorganic layer 51 is an inorganic continuous layer, and the orthographic projection of the inorganic layer 51 on the substrate 20 is located outside the orthographic projection of the seal 30 on the substrate 20. Further, at least a part of the inorganic layer 51 is formed on the outside surface 40A of the connection part 40 (i.e., the side surface of the connection part 40 facing the edge of the substrate 20). The outside surface 40A of the connection part 40 is a surface of the connection part 40 facing away from the sealed member 30 in a direction parallel to the substrate 20.

It should be noted that regarding that the inorganic layer 51 is located at least between the cover plate 10 and the substrate 20, FIG. 2 to FIG. 5 each take the entire inorganic layer 51 as an example that is located between the cover plate 10 and the substrate 20 in the direction perpendicular to the substrate 20. In other embodiments, for example, the inorganic layer 51 may further include a part located at the side edge of at least one of the cover plate 10 and the substrate 20.

Regarding that at least part of the inorganic layer 51 is formed on the outside surface 40A of the connection part 40, FIG. 2, FIG. 4 and FIG. 5 each show that the entire inorganic layer 51 is formed on the outside surface 40A of the connection part 40, and FIG. 3 shows that only a part of the inorganic layer 51 is formed on the outside surface 40A of the connection part 40. In the case where only a part of the inorganic layer 51 is formed on the outside surface 40A of the connection part 40, for example, as shown in FIG. 3, the inorganic layer 51 includes a substrate-side extension part 512, a middle part 513, and a cover plate-side extension part 511, which are sequentially connected. The middle part 513 is formed on the outside surface 40A of the connection part 40, and the substrate-side extension part 512 and the cover plate-side extension part 511 are both located at the outside of the connection part 40, and extend in the direction parallel to the substrate 20. Forming the inorganic layer 51 into a groove structure with a substantially U-shaped cross section as shown in FIG. 3 is helpful to improve the sealing effect.

For example, each of the cover plate 10 and the substrate 20 may be a quartz plate, a glass plate, a plastic plate, or the like.

For example, the sealed member 30 may be an OLED array structure including a plurality of rows and columns of OLED devices (e.g., top-emitting OLED devices) and corresponding switching elements, etc. In other embodiments, the sealed member 30 may be other types of structures that need to be sealed.

For example, the connection part 40 is made by curing an organic resin adhesive. The organic resin adhesive is, for example, an ultraviolet curable resin adhesive or a thermosetting resin adhesive. For example, the resins used to manufacture the organic resin adhesive includes homopolymers or copolymers of monomers such as epoxy resin, propylene oxide acrylate, glycidyl methacrylate, methyl methacrylate, ethyl methacrylate, n-butyl methacrylate, 6,7-epoxyheptyl methacrylate, 2-hydroxyethyl methacrylate, or includes melamine formaldehyde resin, unsaturated polyester resin, silicone resin or furan resin, etc. Materials of the connection part 40 in the embodiments of the present disclosure include, but are not limited to, the above listed materials.

For example, the material of the inorganic layer 51 is at least one or more of inorganic nonmetallic materials such as SiNₓ, SiO₂, SiC, Al₂O₃, SiON, SiCN, etc., which have the characteristics of blocking water and oxygen.

In the embodiments of the present disclosure, for example, as shown in FIG. 2 to FIG. 5, the part of the inorganic layer 51 formed on the connection part 40 is extended from one of the substrate 20 and the cover plate 10 to the other of the substrate 20 and the cover plate 10 in the edge region of the packaging substrate instead of extending in the lateral direction as shown by the inorganic barrier layers 05 and 07 in FIG. 1, that is to say, the extension length of at least part of the inorganic layer 51 formed on the outside surface 40A of the connection part 40 is larger than the thickness of the at least part of the inorganic layer 51 (the thickness is the dimension in the direction parallel to the substrate 20). For example, the thickness of the at least part of the inorganic layer 51 is 0.03 μm to 2.5 μm.

For example, as shown in FIG. 2 to FIG. 5, the at least part of the inorganic layer 51 formed on the outside surface 40A of the connection part 40 has an arc-shaped structure. For example, the inorganic layer 51 having the arc-shaped structure may be formed by first making the outside surface 40A of the connection part 40, on which the inorganic layer 51 is to be formed, be an arc-shaped surface; after that, the inorganic layer 51 is formed on at least the outside surface 40A of the connection part 40 by a deposition method. For example, in order to ensure that the shape of the outside surface 40A of the connection part 40 having the arc-shaped structure is substantially transferred to the inorganic layer 51, the part (i.e., the at least part) of the inorganic layer 51 formed on the outside surface 40A may be in direct contact with the outside surface 40A of the connection part 40.

It should be noted that in other embodiments, the at least part of the inorganic layer 51 can also be in a flat structure with a flat surface or another type of non-arc-shaped structures, so long as the at least part of the inorganic layer 51 is extended from one of the substrate 20 and the cover plate 10 to the other of the substrate 20 and the cover plate 10 in the edge region of the packaging substrate, which is advantageous for the narrow frame design.

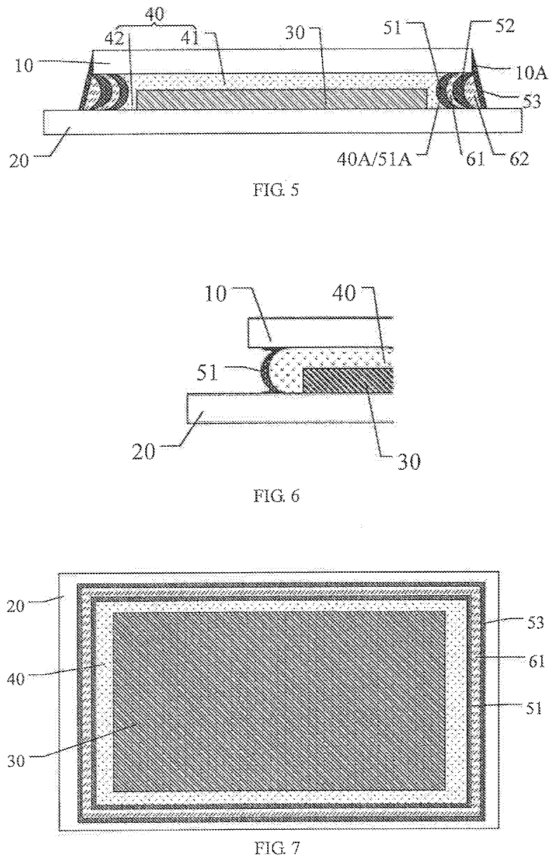

For example, as shown in FIG. 2 to FIG. 5, in the case where the inorganic layer 51 has an arc-shaped structure, the inner surface 51A of the at least part of the inorganic layer 51 formed on the outside surface 40A of the connection part 40 (i.e., the at least part of the surface facing the connection part 40) is a convex surface protruding toward the sealed member 30, for example, a convex arc-shaped surface or other type of convex curved surface. In other embodiments, as shown in FIG. 6, the inner surface of the at least part of the inorganic layer 51 formed on the outside surface 40A of the connection part 40 is a concave arc-shaped surface recessed in a direction away from the sealed member 30. Compared with the way in which the inner surface of the inorganic layer 51 is set as a concave arc-shaped surface (as shown in FIG. 6) or a flat surface, the way in which the inner surface 51A of the inorganic layer 51 is set as the convex surface that is protruding toward the sealed member 30 as shown in FIG. 2 to FIG. 5 facilitates continuous film formation of the inorganic layer 51 in the manufacturing process, avoids weak spots in the film layer, and facilitates the connection between the inorganic layer 51 and the cover plate 10 as well as the substrate 20 to improve the sealing effect of the inorganic layer 51.

For example, in order to further improve the sealing effect, the inorganic layer 51 may be in direct contact with the cover plate 10, or the connection part 40 may be in direct contact with the cover plate, or the inorganic layer 51 and the connection part 40 may be both in direct contact with the cover plate 10, as shown in FIG. 2 to FIG. 5. In other embodiments, when other structures are formed between the cover plate 10 and the inorganic layer 51, the inorganic layer 51 is not in direct contact with the cover plate 10.

The region of the substrate 20 located at the outside of the sealed member 30 includes a wiring region and a non-wiring region. Various wires are provided in the wiring region, and the inorganic layer 51 and the part of the connection part 40 located in the wiring region are all located at the side of these wires facing the cover plate 10. In the non-wiring region, both the inorganic layer 51 and the connection part 40 can be in direct contact with the substrate 20 to further improve the sealing effect, as, shown in FIG. 2 to FIG. 5.

For example, in order to further improve the sealing effect, as shown in FIG. 2 to FIG. 5, the connection part 40 includes a main body part 41 and a peripheral part 42, the main body part 41 covers the sealed member 30, and the peripheral part 42 is located at the periphery of the sealed member 30 and connected to the main body part 41. For example, the upper surface of the main body part 41 is in direct contact with the cover plate 10 to further improve the sealing effect. For example, the main body part 41 fills the gap between the cover plate 10 and the sealed member 30 to avoid air bubbles and to avoid sagging in the middle of the cover plate 10 when the packaging substrate size is large.

For example, as shown in FIG. 2 to FIG. 5, the packaging substrate provided by at least one embodiment of the present disclosure further includes a first organic layer 61 and an outer inorganic layer 53, which are located at the outside of the inorganic layer 51, and the first organic layer 61 is located between the inorganic layer 51 and the outer inorganic layer 53. In other words, the packaging substrate provided by the embodiments of the present disclosure adopts a lateral thin film packaging mode in which inorganic layers and organic layers are alternately stacked, such as an inorganic layer/an organic layer/an inorganic layer, to improve the sealing effect.

For example, the lateral thin film packaging may be implemented by using three-layer thin film stack, and in this case, as shown in FIG. 2 to FIG. 4, the first organic layer 61 is in direct contact with the inorganic layer 51, and is in direct contact with the outer inorganic layer 53.

In other embodiments, thin films of more layers can be used for lateral film packaging to further improve the sealing effect. For example, as shown in FIG. 5, the packaging substrate provided by at least one embodiment of the present disclosure further includes an interlayer inorganic layer 52 and a second organic layer 62, the interlayer inorganic layer 52 and the second organic layer 62 are located between the first organic layer 61 and the outer inorganic layer 53, and the second organic layer 62 is located between the interlayer inorganic layer 52 and the outer inorganic layer 53. For example, the first organic layer 61 is in direct contact with both the inorganic layer 51 and the interlayer inorganic layer 52, and the second organic layer 62 is in direct contact with both the interlayer inorganic layer 52 and the outer inorganic layer 53. In other embodiments, more inorganic layers and more organic layers may be provided according to actual needs.

For example, the materials of the outer inorganic layer 53 and the interlayer inorganic layer 52 may be any combination of at least one or more of the inorganic nonmetallic materials listed above. For example, the materials of the outer inorganic layer 53 and the interlayer inorganic layer 52 may be the same as or different from the inorganic layer 51.

For example, the materials of the first organic layer 61 and the second organic layer 62 are resin adhesives or other similar filler materials.

For example, as shown in FIG. 2 to FIG. 5, the outer inorganic layer 53 is connected to the side surface 10A of the cover plate 10 (e.g., in direct contact or indirect contact) to improve the sealing effect. For example, in order to facilitate the connection between the outer inorganic layer 53 and the side surface 10A of the cover plate 10, the side surface 10A of the cover plate 10 is located between the sealed member 30 and the edge of the substrate 20 in the direction parallel to the substrate 20, that is, the edge of the substrate 20 extends beyond the side surface 10A of the cover plate 10.

For example, in order to further improve the sealing effect, the above-mentioned lateral thin film packaging method can also be combined with other packaging methods. For example, the packaging substrate provided by at least one embodiment of the present disclosure further includes a thin film packaging layer 70 located at one side of the connection part 40 closer to the sealed member 30, the thin film packaging layer 70 covers the sealed member 30, and the periphery of the thin film packaging layer 70 is located at the outside of the sealed member 30 and connected to the substrate 20 (e.g., directly or indirectly connected). For example, the thin film packaging layer 70 is covered by the main body part 41 of the connection part 40 to provide double seal to the sealed member 30.

For example, the material of the thin film packaging layer 70 includes one or more of inorganic nonmetallic materials as described above. The material of the thin film packaging layer 70 may be the same as or different from that of the inorganic layer 51.

For example, the thin film packaging layer 70 is a single-layer film structure, which can improve the sealing effect and help to avoid generating larger shadow parts.

FIG. 7 is a schematic top view of a partial structure of a packaging substrate according to at least one embodiment of the present disclosure. For example, FIG. 7 shows a sealed member 30, a connection part 40, an inorganic layer 51, a first organic layer 61, and an outer inorganic layer 53 which arc located on the substrate 20. The connection part 40 covers the sealed member 30 and includes a part located at the outside of the sealed member 30, the orthographic projection of the inorganic layer 51 on the substrate 20 is located outside the sealed member 30 to form a closed annular structure, similarly, the outer inorganic layer 53 is also in a closed annular structure, and the first organic layer 61 is located between the inorganic layer 51 and the outer inorganic layer 53.

At least one embodiment of the present disclosure provides an electronic device, which includes the packaging substrate according to any one of the above embodiments, and the electronic device is a display device or a light emitting device.

For example, the electronic device can be any product or component with display function such as a display panel, a mobile phone, a tablet computer, a television, a display, a notebook computer, a digital photo frame, a navigator and the like. Or the electronic device can be any product or component with light emitting function such as a lighting device, a backlight source and the like.

At least one embodiment of the present disclosure also provides a packaging method, which includes the following steps S01 to S05.

Step S01: connecting the first base substrate with a second base substrate with a sealed member (e.g., located in a display area or a light emitting area) by a paste. A pressing mould located at the periphery of the sealed member (e.g., located in a non-display area or a non-light emitting area) is disposed between the first base substrate and the second base substrate. For example, a plurality of sealed members that are spaced apart from each other are formed on the second base substrate, and each of the sealed members is surrounded by a pressing mould.

For example, in step S01, the thickness of the pressing mould is approximately equal to the distance between the cover plate and the substrate (i.e., a target cell thickness) of the packaging substrate to be formed. For example, according to the size of the target cell thickness, the thickness of the pressing mould ranges from 5 μm to 30 μm.

For example, in step S01, the side surface of the pressing mould is a convex cambered surface, so that the outside surface formed by the paste that is subjected to the subsequent press processing is a concave cambered surface.

For example, in step S01, the surface of the pressing mould close to the paste may be coated with a release agent to prevent the connection part that is formed after the paste is solidified, in the subsequent step, from adhering to the pressing mould, and lubricating the contact surface between the pressing mould and the first base substrate and the second base substrate, thereby facilitating the removal of the pressing mould in the subsequent step. For example, the release agent includes alkyl polymer, silicone oil, polytetrafluoroethylene powder, polyethylene glycol or low molecular weight polyethylene and other materials.

For example, in step S01, the viscosity of the paste is from 100 MPa/s to 2000 MPa/s, which is advantageous for the paste to fill the gap between the first base substrate and the sealed member through the fluidity of the paste, thus ensuring that the subsequently formed connection part fills the gap between the cover plate and the sealed member.

Step S02: performing a press processing on the paste.

For example, in step S02, the press processing is performed on the paste in a vacuum environment to prevent bubbles from being generated in the paste.

For example, in step S02, the paste may be pressed by applying pressure to the first base substrate or to the second base substrate, or to both the first base substrate and the second base substrate. Based on the above case, for example, the paste can be pressed by applying a force to the paste from the side of the paste by moving the pressing mould (for example, the direction of the force is perpendicular to the direction in which the first base substrate and the second base substrate are aligned) to press the paste.

Step S03: curing the paste that has been subjected to the press processing to mould the paste, thus obtaining the connection part connecting the first base substrate and the second base substrate.

For example, in step S03, the paste may be cured by an ultraviolet light irradiation method, a heating method or other methods.

Step S04: cutting the first base substrate and the second base substrate to obtain a cover plate and a substrate, respectively.

For example, in step S04, the second base substrate is cut at a position between adjacent sealed members, so that the second base substrate is cut into a plurality of substrates, and for example each of the plurality of substrates is formed with one sealed member. For example, the sealed member is an OLED array structure (in this case, the area where each of the sealed members is located is a display area or a light emitting area) or a similar array structure. Similarly, corresponding positions of the first base substrate are cut to obtain a plurality of cover plates, and each of the plurality of cover plates is correspondingly connected with one substrate,

For example, in step S04, after the cutting of the first base substrate and the second base substrate is completed, the pressing mould is removed from the outside surface of the connection part to separate the pressing mould from the connection part.

Step S05: forming an inorganic layer at the outside of the connection part and between the cover plate and the substrate. At least part of the inorganic layer is formed on the outside surface of the connection part, and an orthographic projection of the inorganic layer on the substrate is located outside the orthographic projection of the sealed member on the substrate.

For example, in step S05, forming the inorganic layer includes: forming a removable layer on the cover plate and the substrate; forming an inorganic layer thin film covering the removable layer and the outside surface of the connection part; and removing the removable layer to obtain an inorganic layer. The inorganic layer thin film is patterned by using the removable layer to obtain the inorganic layer, thus a mask plate can be saved, and the cost can be reduced. For example, the removable layer may be a high-temperature resistant and corrosion resistant adhesive tape, or a similar patch with lower viscosity.

For example, in step S05, for example, the inorganic layer 51 may be formed by a chemical vapor deposition (CVD) method, a sputtering method, an atomic layer deposition (ALD) method, or the like. For example, the inorganic layer is formed by the atomic layer deposition method. The atomic layer deposition (ALD) method is a method of forming a deposited thin film by alternately introducing gas precursors in a manner of pulse into a reactor to conduct chemical adsorption and reaction on a deposition substrate. Compared with a chemical vapor deposition (CVD) method or the like method, the atomic layer deposition method is not a continuous process, because different reaction precursors are alternately fed into the reaction chamber of the reactor in the form of gas pulses, thus having obvious advantages in film uniformity, step coverage rate, thickness control and the like, being especially suitable for film deposition on uneven surfaces and having a good gap filling function.

For example, after step S05 is completed, the packaging method provided by at least one embodiment of the present disclosure further includes sequentially forming the first organic layer and the outer inorganic layer on the outside of the inorganic layer, or sequentially forming the first organic layer, the interlayer inorganic layer, the second organic layer, and the outer inorganic layer on the outside of the inorganic layer. The arrangement of these layers can be described with reference to the above embodiments of the packaging substrate.

For example, before connecting the first base substrate and the second base substrate which is formed with the sealed member by the paste (i.e., before step S01 above), the packaging method provided by at least one embodiment of the present disclosure further includes forming a paste pattern on the first base substrate or on the second base substrate, so that the paste pattern does not completely overlap the region corresponding to the sealed members, that is, the paste pattern does not cover the entire region corresponding to the sealed members of the substrate on which the paste pattern is located. In this way, after the first base substrate and the second base substrate are connected by the paste pattern, and when the press processing is performed on the paste pattern, it is beneficial for the paste to fill the gap between the first base substrate and the sealed member due to the fluidity of the paste, thus ensuring that the subsequently formed connection part fills the gap between the cover plate and the sealed member.

For example, the paste pattern may include a linear pattern such as a concentric circle pattern. In this case, for example, the thickness of the paste pattern is 1.5-3 times as large as the distance (e.g., 5 microns to 10 microns) between the cover plate and the substrate. This is advantageous for the subsequently formed connection part to fill the gap between the cover plate and the sealed member, and to prevent the part of the connection part, between the cover plate and the substrate, from being too thick.

For example, the paste pattern can be formed by a glue dispensing method (for example, Dam & Fill mode). The glue dispensing method is beneficial for forming a thin paste pattern suitable for the distance between the cover plate and the substrate.

For example, the paste pattern may be coated on the first base substrate, and then the first base substrate coated with the paste pattern and the second base substrate formed with the sealed member are opposed to each other and connected through the paste pattern. This is helpful to avoid discarding the substrate due to errors in coating the paste.

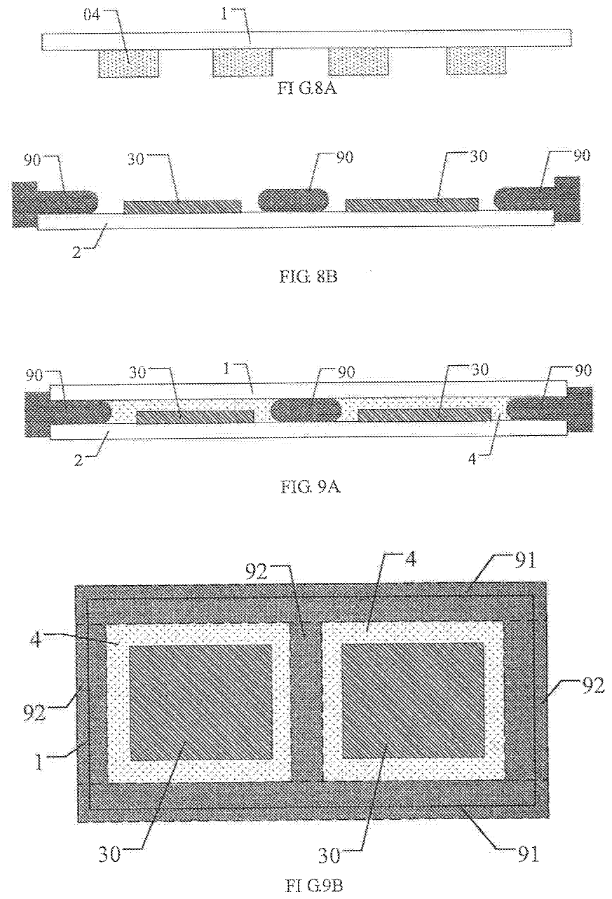

The packaging method provided by the embodiments of the present disclosure is illustrated below with reference to FIG. 8A to FIG. 14, for example, the manufacturing method provided by at least one embodiment of the present disclosure includes the following steps S1 to S10.

Step S1: as shown in FIG. 8A, forming a paste pattern 04 with a linear shape on the first base substrate 1, so that the paste pattern 04 does not completely overlap with the regions of the first base substrate 1 corresponding to the sealed members. As shown in FIG. 8B, a pressing mould 90 coated with a release agent and having a convex arc-shaped surface is placed on the second base substrate 2, on which a plurality of sealed members 30 are formed or provided, so that the pressing mould 90 surrounds the sealed members 30.

For example, in step S1, the distance (i.e., the target cell thickness) between the cover plate and the substrate, in the packaging substrate to be formed, is 10 μm, and the thickness of the pressing mould 90 is also 10 μm.

In this step S1, the process of forming the paste pattern 04 on the first base substrate 1, and the process of manufacturing the sealed members 30, and arranging the pressing mould 90 on the second base substrate 2 are not limited in the above order.

Step S2: connecting the first base substrate 1 and the second base substrate 2 by using the paste of the paste pattern 04, so that the sealed members 30 and the pressing mould 90 are positioned between the first base substrate 1 and the second base substrate 2.

Step S3: as shown in FIG. 9A and FIG. 9B, pressing the first base substrate 1 and the second base substrate 2 together, so that the paste 4 flows to the first extension part 91 of the pressing mould 90 and the second extension part 92 of the pressing mould 90 (these extension parts cross each other to form a grid shape, as shown in FIG. 9B), and fills the gap between the first base substrate 1 and the second base substrate 2. In this case, the paste 4 includes a part covering the sealed members 30 and a part located at the periphery of the sealed members 30, and the paste 4 is extruded to form the outside surface which is the concave arc-shaped surface due to pressing.

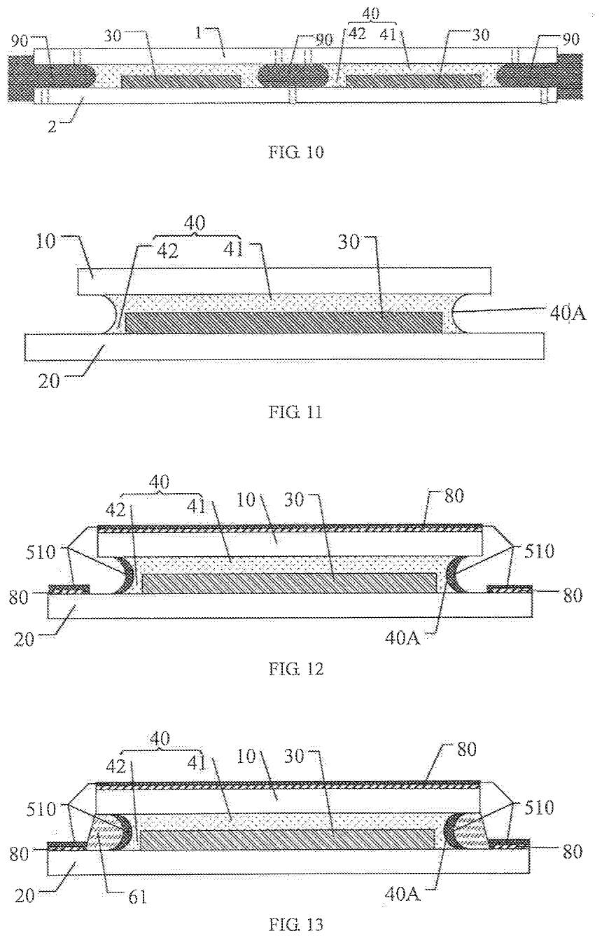

Step S4: curing the paste 4 after the press processing to obtain a connection part 40 connecting the first base substrate 1 and the second base substrate 2, and including a main body part 41 and a peripheral part 42, as shown in FIG. 10.

Step S5: cutting the positions of the first base substrate 1 and the second base substrate 2 between the adjacent sealed members 30 (as shown in FIG. 10), and then removing the pressing mould 90 to obtain the cover plate 10 and the substrate 20 connected together by the connection part 40 as shown in FIG. 11. The outside surface 40A of the connection part 40 is a concave arc-shaped surface.

Step S6: as shown in FIG. 12, forming a removable layer 80 on the substrate 20 such that the removable layer covers the entire upper surface of the cover plate 10 and covers the part of the substrate 20 beyond the cover plate 10.

Step S7: as shown in FIG. 12, forming an inorganic layer thin film 510 by, for example, the atomic layer deposition method, so that the inorganic layer thin film 510 covers the removable layer 80, and covers the entire outer surface 40A of the connection part 40.

For example, in this step S7, the inorganic layer thin film 510 is an Al₂O₃ film with the thickness of 30 nm.

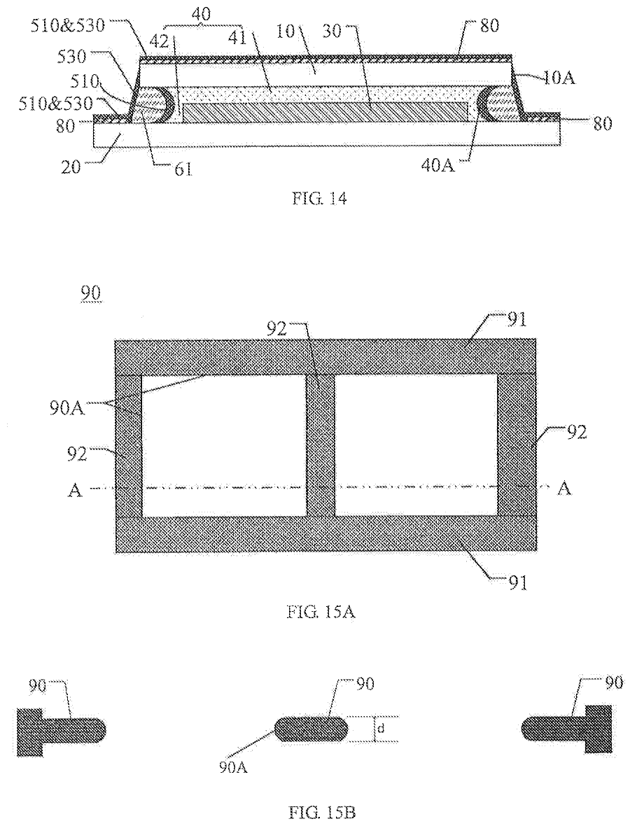

Step S8: as shown in FIG. 13, forming a first organic layer 61 at the outside of the part of the inorganic layer thin film 510 located at the outside surface 40A and between the cover plate 10 and the substrate 20. For example, the paste for forming the first organic layer 61 is coated by a dispensing method, or the like, and then the paste is cured to obtain the first organic layer 61.

Step S9: as shown in FIG. 14, forming an outer inorganic layer thin film 530 by, for example, the atomic layer deposition method, so that the outer inorganic layer thin film 530 covers the removable layer 80, and covers the outside surface of the first organic layer 61 and the side surface 10A of the cover plate 10.

For example, in this step S9, the outer inorganic layer thin film 530 is an Al₂O₃ film with the thickness of 30 nm.

Step S10: removing the removable layer 80. So that the inorganic layer 51 and the outer inorganic layer 53 which are located between the cover plate 10 and the substrate 20 and also located at the outside of the connection part 40 can be obtained as shown in FIG. 2 or FIG. 3.

For the packaging method of the packaging substrate as shown in FIG. 4, it is necessary to cover each of the sealed members 30 with the corresponding thin film packaging layer 70 in the above-mentioned step S1, and the remaining steps are similar to the above-mentioned steps S2 to S10.

For the packaging method of the packaging substrate as shown in FIG. 5, in the above-mentioned step S8, the paste for forming the first organic layer 61 is cured after being pressed by a press mould coated with a release agent; then, the thin films for forming an interlayer inorganic layer, a second organic layer 62, and an outer inorganic layer thin film 530 are sequentially formed. The inorganic layer 51, the interlayer inorganic layer 52, and the outer inorganic layer 53, which are located between the cover plate 10 and the substrate 20 and are all located outside the connection part 40, as shown in FIG. 5, can be obtained after removing the removable layer 80.

At least one embodiment of the present disclosure also provides a packaging method, taking the packaging substrate shown in FIG. 2 to FIG. 5 as an example, the packaging method includes: connecting the cover plate 10 and the substrate 20 formed with the sealed member 30 by using a paste, wherein a pressing mould positioned at the periphery of the sealed member 30 is arranged between the cover plate 10 and the substrate 20; performing a press processing on the paste; curing the paste that has been subjected to the press processing, to obtain a connecting part 40 connecting the cover plate 10 and the substrate 20; and forming an inorganic layer 51 on the outside of the connection part 40 and between the cover plate 10 and the substrate 20, wherein at least a part of the inorganic layer 51 is formed on the outside surface of the connection part 40, and an orthographic projection of the inorganic layer 51 on the substrate 20 is located outside the orthographic projection of the sealed member 30 on the substrate 20.

In the above-mentioned packaging method, the arrangement mode of each component can refer to the description relevant to the above-mentioned embodiments of the packaging substrate, and the formation and curing of the paste, the press processing and the formation mode of each component can refer to the description relevant to the above-mentioned embodiments of the packaging method including the cutting step.

At least one embodiment of the present disclosure also provides a pressing mould for the packaging method according to any one of the above embodiments. As shown in FIGS. 15A and FIGS. 15B, the pressing mould 90 includes a plurality of first extension parts 91 that are spaced apart from each other, and a plurality of second extension parts 92 that are spaced apart from each other, the plurality of first extension parts 91 and the plurality of second extension parts 92 cross each other to form a grid-shaped structure, and the adjacent side surfaces 90A of the adjacent first extension parts 91 and the adjacent side surfaces 90A of the adjacent second extension parts 92 are arc-shaped surfaces. For example, the side surfaces 90A are convex cambered surfaces, so that the paste extruded by the pressing mould has a concave cambered surface.

For example, the first extension parts 91 of the pressing mould 90 and the second extension parts 92 of the pressing mould 90 are connected with each other in a detachable connection manner so as to remove the pressing mould after curing the paste that has been subjected to the press processing. For example, the detachable connection may be snap connection, threaded connection or other commonly used detachable connection methods, and the embodiments of the present disclosure are not limited.

For example, the thickness d of the pressing mould 90 (as shown in FIG. 15B) ranges from 5 μm to 30 μm.

For example, the material of the pressing mould 90 is acrylic, polystyrene, metal or other types of materials. The embodiments of the present disclosure are not limited to these examples.

To sum up, the embodiments of the present disclosure has at least one of the following advantages. (1) The lateral inorganic layer is combined with a cover plate with strong water resistance to realize packaging, so that a shadowing effect is not generated, and a better packaging effect can be achieved on the premise of a narrower frame. (2) The outside surface of the connection part connecting the cover plate and the substrate is controlled to form a regular concave arc-shaped surface through a pressing mould, which is helpful for continuously fanning the inorganic layer in the manufacturing process so as to prevent weak points of the film layer. (3) In some embodiments, under the action of the release agent, the pressing mould can be smoothly separated from the connection part formed by curing, and the circuits provided on the substrate can be prevented from being scratched.

The following points need to be explained: (1) in the drawings of the embodiments of the present disclosure, only the structures related to the embodiments of the present disclosure are involved, and other structures can be referred to the common design; (2) without conflict, the embodiments of the present disclosure and the features in the embodiments may be combined with each other.

What are described above is related to the illustrative embodiments of the disclosure only and not limitative to the scope of the disclosure; the scopes of the disclosure are defined by the accompanying claims.

1. A packaging substrate, comprising;
a cover plate and a substrate, which are oppositely arranged;
a sealed member, positioned between the cover plate and the substrate;
a connection part, connecting the cover plate and the substrate and comprising a part located at a periphery of the sealed member; and
an inorganic layer, located at an outside of the connection part facing away from the sealed member and located at least between the cover plate and the substrate,
wherein at least a part of the inorganic layer is formed on an outside surface of the connection part, the outside surface of the connection part is a surface of the connection part facing away from the sealed member in a direction parallel to the substrate, and an orthographic projection of the inorganic layer on the substrate is located outside an orthographic projection of the sealed member on the substrate.

2. The packaging substrate according to claim 1, wherein the at least part of the inorganic layer is in direct contact with the connection part; and/or the inorganic layer is in direct contact with the cover plate.

3. The packaging substrate according to claim 1, wherein an extension length of the at least part of the inorganic layer is greater than a thickness of the at least part of the inorganic layer.

4. The packaging substrate according to claim 1, wherein the inorganic layer comprises a substrate-side extension part, a middle part, and a cover plate-side extension part, which are sequentially connected, the middle part is formed on the outside surface of the connection part, and
the substrate-side extension part and the cover plate-side extension part are both extended in the direction parallel to the substrate, and are located at the outside of the connection part.

5. The packaging substrate according to claim 1, wherein the at least part of the inorganic layer has an arc-shaped structure.

6. The packaging substrate according to claim 5, wherein an inner surface of the at least part of the inorganic layer is a convex surface protruding toward the sealed member, and the inner surface is at last a part of a surface facing the sealed member.

7. The packaging substrate according to claim 1, wherein the connection part is in direct contact with the cover plate.

8. The packaging substrate according to claim 1, wherein the connection part comprises a main body part covering the sealed member, and a peripheral part located at a periphery of the sealed member and connected to the main body part.

9. The packaging substrate according to claim 1, wherein the outside surface of the connection part, on which the inorganic layer is formed, is an arc-shaped surface.

10. The packaging substrate according to claim 1, further comprising:
a first organic layer and an outer inorganic layer, which are both located at an outside of the inorganic layer,
wherein the outside of the inorganic layer is a side of the inorganic layer facing away from the sealed member in the direction parallel to the substrate; and
in the direction parallel to the substrate, the first organic layer is located between the inorganic layer and the outer inorganic layer.

11. The packaging substrate according to claim 10, wherein the outer inorganic layer is connected with a side surface of the cover plate.

12. The packaging substrate according to claim 10, further comprising:
an interlayer inorganic layer and a second organic layer, in the direction parallel to the substrate, located between the first organic layer and the outer inorganic layer,
wherein the second organic layer is located between the interlayer inorganic layer and the outer inorganic layer in the direction parallel to the substrate,

13. The packaging substrate according to claim 1, further comprising
a thin film packaging layer located at a side of the connection part facing the sealed member,
wherein the thin film packaging layer covers the sealed member, and a periphery of the thin film packaging layer is located outside the sealed member and connected with the substrate.

14. An electronic device, comprising:
the packaging substrate according to claim 1, wherein the electronic device is a display device or a light emitting device.

15. A packaging method, comprising:
connecting a first base substrate and a second base substrate formed with a sealed member by using a paste, wherein a pressing mould located at a periphery of the sealed member is arranged between the first base substrate and the second base substrate;
performing a press processing on the paste;
curing the paste that has been subjected to the press processing to obtain a connecting part connecting the first base substrate and the second base substrate;
cutting the first base substrate and the second base substrate to obtain a cover plate and a substrate respectively; and
forming an inorganic layer on an outside of the connection part facing away from the sealed member and at least between the cover plate and the substrate,
wherein at least a part of the inorganic layer is formed on an outside surface of the connection part, the outside surface of the connection part is a surface of the connection part facing away from the sealed member in a direction parallel to the substrate, and an orthographic projection of the inorganic layer on the substrate is located outside an orthographic projection of the sealed member on the substrate.

16. (canceled)

17. The packaging method according to claim 15, wherein forming the inorganic layer comprises:
forming a removable layer on the cover plate and the substrate;
forming an inorganic layer thin film covering an outer surface of the removable layer and an outer surface of the connection part; and
removing the removable layer to obtain the inorganic layer, wherein the inorganic layer is formed by an atomic layer deposition method.

18. The packaging method according to claim 15, wherein a surface of the pressing mould facing the paste is coated with a release agent.

19. The packaging method according to claim 15, wherein before connecting the first base substrate and the second base substrate formed with the sealed member by using the paste, a paste patter is formed on the first base substrate or the second base substrate, and
a region corresponding to the paste pattern does not completely overlap with a region corresponding to the sealed member, and a thickness of the paste pattern is 1.5-3 times as large as a distance between the cover plate and the substrate.

20. (canceled)

21. A packaging method, comprising:
connecting a cover plate with a substrate on which a sealed member is formed by using a paste, wherein a pressing mould located at a periphery of the sealed member is arranged between the cover plate and the substrate;
performing a press processing the paste;
curing the paste that has subjected to the press processing to obtain a connecting part connecting the cover plate and the substrate; and
forming an inorganic layer on an outside of the connection part facing away from the sealed member, and at least between the cover plate and the substrate,
wherein at least a part of the inorganic layer is formed on an outside surface of the connection part, the outside surface of the connection part is a surface of the connection part facing away from the sealed member in a direction parallel to the substrate, and an orthographic projection of the inorganic layer on the substrate is located outside an orthographic projection of the sealed member on the substrate.

22. A press mould for the packaging method according to claim 15 or the packaging method according to claim 20, comprising:
a plurality of first extension parts and a plurality of second extension parts, wherein the plurality of first extension parts and the plurality of second extension parts cross each other to form a grid-like structure, and oppositely facing side surfaces of adjacent first extension parts and oppositely facing side surfaces of adjacent second extension parts are arc-shaped surfaces.
